(19) United States
(12) Patent Application Publication
(10) Pub. No.: US 2024/0250224 A1
(43) Pub. Date: Jul. 25, 2024

(54) SURFACE LIGHT SOURCE DEVICE AND DISPLAY DEVICE

(71) Applicant: Enplas Corporation, Kawaguchi-shi (JP)

(72) Inventor: Masaki NOGAMI, Kawaguchi-shi (JP)

(21) Appl. No.: 18/408,705

(22) Filed: Jan. 10, 2024

(30) Foreign Application Priority Data
Jan. 20, 2023 (JP) 2023-007207

(51) Int. Cl. H01L 33/58; H01L 25/075

(52) U.S. Cl. CPC H01L 33/58; H01L 25/0753

(57) ABSTRACT

A surface light source device of the present invention includes light-emitting devices, a light diffusion plate and an optical sheet. The light-emitting devices are disposed at respective intersections of a grid composed of X-direction lines and Y-direction lines, and each light-emitting device includes a light-emitting element and a light flux controlling member. The light-emitting element includes two LED chips aligned in direction a and a phosphor. Cy>Cy2 is satisfied where Cy1 and Cy2 are y-values of the chromaticity coordinates of a first intersection and a second intersection, respectively, on a virtual circle with a radius of d/2 in each light-emitting device, d representing the distance on the diagonal line of the grid. Each light-emitting element is disposed such that a point where Cy is greater than Cy2 is located on a line parallel to the diagonal line of the grid on the virtual circle.

### CROSS REFERENCE TO RELATED APPLICATIONS

This application is entitled to and claims the benefit of Japanese Patent Application No. 2023-007207, filed on Jan. 20, 2023, the disclosure of which including the specification, drawings and abstract is incorporated herein by reference in its entirety.

### TECHNICAL FIELD

The present invention relates to a surface light source device, and a display device including the surface light source device.

### BACKGROUND ART

Some transmissive-image display devices such as liquid crystal display devices use a direct surface light source device as a backlight. In recent years, direct surface light source devices including a plurality of light-emitting devices as the light source are increasingly used. For example, PTL 1 discloses such a surface light source device (display device).

### CITATION LIST

### Patent Literature

### PTL 1

Japanese Patent Application Laid-Open No. 2010-278426

### SUMMARY OF INVENTION

### Technical Problem

FIG. 1A illustrates the inside of exemplary surface light source device 10. As illustrated in FIG. 1A, surface light source device 10 includes a plurality of light-emitting devices 200, and the plurality of light-emitting devices 200 is disposed in a grid. More specifically, as illustrated in FIG. 1A, the plurality of light-emitting devices 200 is disposed at respective intersections of a grid composed of a plurality of X-direction lines 1 extending in the X direction and a plurality of Y-direction lines 2 extending in the Y direction perpendicular to the X direction.

FIG. 1B is a partial sectional view of surface light source device 10 (a sectional view of a light-emitting device). As illustrated in FIG. 1B, each light-emitting device 200 disposed as described above includes light-emitting element 220, and light flux controlling member (lens) 300 for controlling light from light-emitting element 220. Light from light-emitting element 220 is controlled by light flux controlling member 300, the controlled light reaches light diffusion plate 120 and optical sheet 130, and the light having reached light diffusion plate 120 and optical sheet 130 is diffused. In this manner, surface light source device 10 functions as a light source.

FIG. 2A is a diagram illustrating a state where the above-mentioned light flux controlling member 300 is removed from light-emitting device 200 in FIG. 1A such that light-emitting element 220 is visible. In addition, FIG. 2B is a partially enlarged view of FIG. 2A. As illustrated in FIG. 2B, light-emitting element 220 includes blue LED chip 221, and yellow phosphor 222 that emits fluorescence in response to light from blue LED chip 221.

It is necessary for the above-described light-emitting element 220 to provide white light at the light-emitting surface of the surface light source device with a combination of blue light from blue LED chip 221 and yellow light from yellow phosphor 222. In addition, in some cases such a light-emitting element 220 may include two blue LED chips 221 as illustrated in FIG. 2B. The present inventors found that, in such a case, ideal white light may not be obtained from the light-emitting surface of surface light source device 10 when direction a in which two blue LED chips 221 are arranged and the X direction or the Y direction in which light-emitting devices 200 are arranged are parallel to each other as illustrated in FIG. 2B. More specifically, when direction a and the X direction or the Y direction are parallel to each other, uneven color may be generated (strong blue may be generated) in the region around intersection 4 of the two diagonal lines 3 of the grid illustrated in FIG. 2B at the light-emitting surface of surface light source device 10. Note that this problem is not limited to the combination of blue LED chip 221 and yellow phosphor 222, but applies to all cases for obtaining light of an intended color with no uneven color with a combination of an LED chip and a phosphor. Examples of such cases include a case for obtaining white light in which light from an LED chip and light from a phosphor has a relationship of complementary color.

An object of the present invention is to provide a surface light source device that can suppress generation of uneven colors. In addition, an object of the present invention is to provide a display device including the surface light source device.

### Solution to Problem

The present invention provides the following surface light source device and display device.

[1] A surface light source device including: a plurality of light-emitting devices disposed on a substrate; a light diffusion plate separated from the plurality of light-emitting devices and disposed on a side opposite to the substrate with respect to the plurality of light-emitting devices; and an optical sheet disposed on a side opposite to the plurality of light-emitting devices with respect to the light diffusion plate. The plurality of light-emitting devices is disposed at respective intersections of a grid including a plurality of X-direction lines extending in a X direction and a plurality of Y-direction lines extending in a Y direction perpendicular to the X direction, each of the plurality of light-emitting devices includes a light-emitting element and a light flux controlling member, the light-emitting element includes two LED chips aligned in a direction a and configured to emit light of a first color, and a phosphor disposed to cover the LED chip and a periphery of the LED chip and configured to convert the light of the first color into light of a second color, Cy1>Cy2 is satisfied when d represents a distance between a center of a light-emitting surface of a given light-emitting element and a center of a light-emitting surface of an adjacent light-emitting element on a diagonal line of the grid, it is assumed that in each of the plurality of light-emitting devices, the light-emitting element is disposed such that the direction a and the X direction are parallel to each other, Cy1 is a y-value of chromaticity coordinates at a first intersection C1, and Cy2 is a y-value of chromaticity coordinates at a second intersection C2, the first intersection C1 being a point where a line passing through a point O and being parallel to the direction a and a virtual circle intersect each other, the second intersection C2 being a point where a line passing through the point O and being parallel to the diagonal line of the grid and the virtual circle intersect each other, the virtual circle being a circle with a radius of d/2 around the point O located directly above a center of a light-emitting surface of the light-emitting element and set on a surface of the light diffusion plate on the light-emitting device side, and each of the plurality of light-emitting elements is disposed such that a point where Cy is greater than Cy2 is located on a line parallel to the diagonal line of the grid on the virtual circle.
[2] The surface light source device according to [1], in which ΔCy>0.003 holds, where Cy1-Cy2 is ΔCy.
[3] The surface light source device according to [1] or [2], in which each of the plurality of light-emitting elements is disposed such that a point where Cy is greater than (Cy1+Cy2)/2 is located on a line parallel to the diagonal line of the grid on the virtual circle.
[4] The surface light source device according to any of [1] to [3], in which each of the plurality of light-emitting elements is disposed such that a point where Cy is Cy1 is located on a line parallel to the diagonal line of the grid on the virtual circle.
[5] The surface light source device according to any of [1] to [4], in which a difference between a maximum value of Cy and a minimum value of Cy in the surface light source device is 0.008 or smaller.
[6] The surface light source device according to any of [1] to [5], in which the optical sheet is a prism sheet, a diffusion sheet, a DBEF, or a combination of two or more of them.
[7] The surface light source device according to any of [1] to [6], in which the LED chip has a rectangular shape in plan view.
[8] The surface light source device according to any of [1] to [7], in which the light-emitting surface of the light-emitting element has a circular shape in plan view.
[9] The surface light source device according to any of [1] to [8], in which an incidence surface and an emission surface of the light flux controlling member are circularly symmetrical.
[10] A display device including: the surface light source device according to any of [1] to [9]; and a display member configured to be irradiated with light emitted from the surface light source device.

### Advantageous Effects of Invention

According to the present invention, it is possible to provide a surface light source device that can suppress generation of uneven colors. In addition, according to the present invention, it is possible to provide a display device including the surface light source device.

### BRIEF DESCRIPTION OF DRAWINGS

FIG. 1A is a diagram illustrating an arrangement of light-emitting devices in a surface light source device, and FIG. 1B is a sectional view of the light-emitting device in the surface light source device;

FIGS. 2A and 2B are diagrams illustrating an arrangement of the light-emitting elements in the surface light source device;

FIGS. 3A and 3B are diagrams illustrating a configuration of a surface light source device according to an embodiment;

FIG. 4A is a diagram illustrating an arrangement of light-emitting devices in the surface light source device according to the embodiment, and FIG. 4B is a sectional view of the light-emitting device in the surface light source device;

FIGS. 5A to 5E are diagrams illustrating a light flux controlling member;

FIG. 6A is a diagram illustrating an arrangement of the light-emitting elements in the surface light source device according to the embodiment, and FIG. 6B is a partially enlarged view of FIG. 6A;

FIGS. 7A and 7B are diagrams illustrating an arrangement of the light-emitting elements in the surface light source device according to the embodiment;

FIG. 8 is a sectional view of the light-emitting element; and

FIG. 9A is a diagram illustrating a simulation result of a chromaticity distribution in a surface light source device of a comparative example, and FIG. 9B is a diagram illustrating a simulation result of a chromaticity distribution in the surface light source device according to the embodiment.

### DESCRIPTION OF EMBODIMENTS

A display device and a surface light source device according to preferable embodiments of the present invention are described below with reference to the accompanying drawings. Note that the drawings are intended for the description, and may not necessarily illustrate the actual scales and the like.

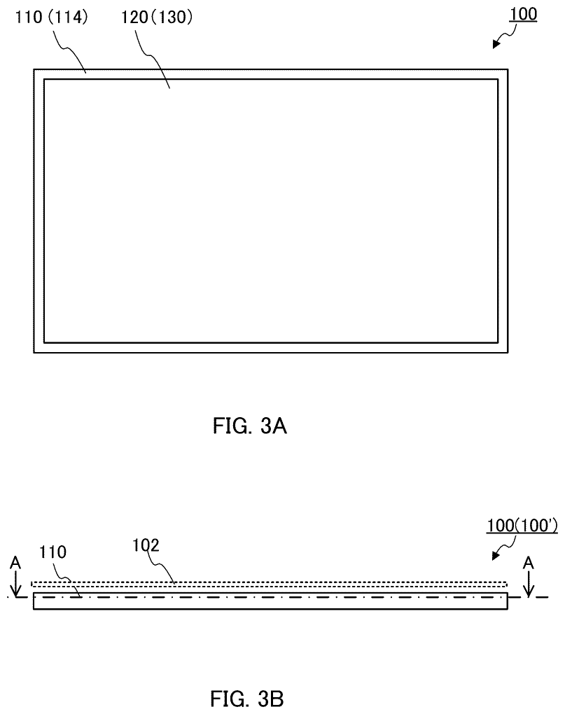

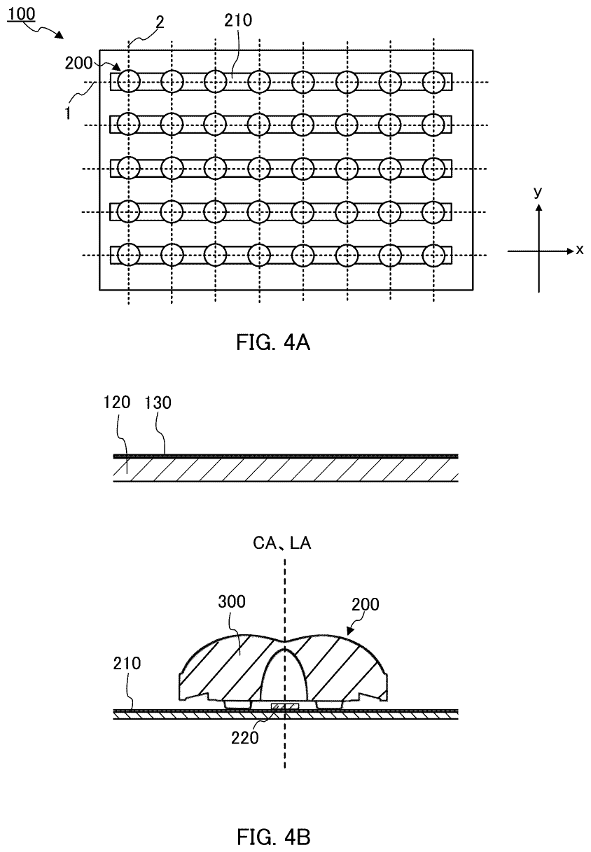

Display Device and Surface Light Source Device FIGS. 3A and 3B are diagrams illustrating an external appearance of surface light source device 100 according to an embodiment of the present invention. FIG. 3A is a plan view of surface light source device 100, and FIG. 3B is a front view. FIG. 4A is a sectional view taken along line A-A of FIG. 3B. In addition, FIG. 4B illustrates a cross-section of light-emitting device 200 in surface light source device 100. As illustrated in FIG. 3A, surface light source device 100 includes housing 110 and light diffusion plate 120. In addition, as illustrated in FIG. 4A, surface light source device 100 includes optical sheet 130.

As illustrated in FIG. 3B, surface light source device 100 can be used as display device 100′ when combined with display member (irradiated member) 102 (e.g., liquid crystal panel) configured to be irradiated with light from surface light source device 100.

As illustrated in FIGS. 3A to 4B, surface light source device 100 according to the present embodiment includes housing 110, a plurality of light-emitting devices 200, light diffusion plate 120, and optical sheet 130. The plurality of light-emitting devices 200 is disposed in a grid on bottom plate 112 of housing 110. Preferably, the inner surface of bottom plate 112 functions as a diffusive reflection surface. In addition, a rectangular opening is provided in top plate 114 of housing 110. Light diffusion plate 120 is disposed to close the opening, and separated from the plurality of light-emitting devices 200 on the side opposite to substrate 210 with respect to the plurality of light-emitting devices 200 to function as a light-emitting surface. The size of the light-emitting surface is not limited, and is approximately 400 mm×approximately 700 mm, for example.

Optical sheet 130 is disposed on the side opposite to the plurality of light-emitting devices 200 with respect to light diffusion plate 120. In the present embodiment, optical sheet 130 is disposed on light diffusion plate 120. Optical sheet 130 may be composed of a single sheet-like member, or a plurality of sheet-like members. In the present embodiment, optical sheet 130 is composed of a plurality of sheet-like members. More specifically, optical sheet 130 needs only to be a prism sheet, a diffusion sheet, or a DBEF, or a combination of two or more of them.

As illustrated in FIGS. 4A and 4B, surface light source device 100 includes the plurality of light-emitting devices 200, and each of the plurality of light-emitting devices 200 includes light flux controlling member 300 and light-emitting element 220. Each component is described below. Note that in the present embodiment, the plurality of light-emitting devices 200 is disposed on substrate 210. In the present embodiment, a plurality of substrates 210 is provided, and each substrate 210 is a rectangular member extending in the X direction.

### Light-Emitting Device

Light-emitting device 200 is a light source of surface light source device 100. As illustrated in FIG. 4A, light-emitting device 200 is disposed at each intersection of a grid composed of a plurality of X-direction lines 1 extending in the X direction and a plurality of Y-direction lines 2 extending in the Y direction perpendicular to the X direction. Note that the distance between the plurality of X-direction lines 1 may or may not be constant. Likewise, the distance between the plurality of Y-direction lines 2 may or may not be constant. In the present embodiment, the distance between the plurality of X-direction lines 1 and the distance between the plurality of Y-direction lines 2 are each constant. Note that preferably, light-emitting device 200 is disposed such that central axis CA of light flux controlling member 300 coincides with the intersection of the grid in plan view. Note that X-direction line 1 and Y-direction line 2 are virtual lines for describing the arrangement of the light-emitting device.

The shape of the grid (each grid section) composed of the plurality of X-direction lines 1 and the plurality of Y-direction lines 2 needs only to be a rectangular shape (including a square shape). Preferably, regarding the ratio of the lengths of the grid (each grid section) in the X direction and the Y direction, the length in the Y direction with respect to 1 set as the length in the X direction is, but not limited to, 0.9 to 1.5, more preferably 1 to 1.3, still more preferably 1.1, for example.

### Light Flux Controlling Member

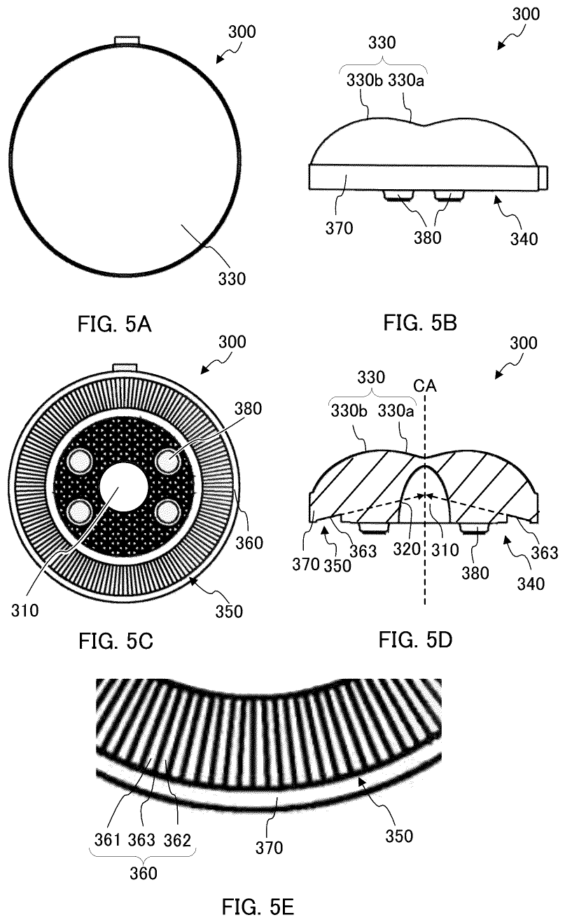

FIGS. 5A to 5E are diagrams illustrating a configuration of light flux controlling member 300. FIG. 5A is a plan view of light flux controlling member 300, FIG. 5B is a side view, FIG. 5C is a bottom view, FIG. 5D is a sectional view, and FIG. 5E is a partially enlarged view of FIG. 5C.

As illustrated in FIGS. 5D and 5E, light flux controlling member 300 includes recess 310, incidence surface 320, emission surface 330, rear surface 340, reflection part 350, ridge 360, flange part 370, and leg part 380.

Recess 310 is disposed at a center portion on the rear side (light-emitting element 220 side) of light flux controlling member 300. The inner surface of recess 310 functions as incidence surface 320. Incidence surface 320 allows most of light emitted from light-emitting element 220 to enter light flux controlling member 300 while controlling the travelling direction of the light. As such, in light flux controlling member 300, incidence surface 320 is disposed to face light-emitting element 220. Incidence surface 320 intersects central axis CA of light flux controlling member 300, and is rotationally symmetrical (circularly symmetrical) about central axis CA. For example, the shape of recess 310 is, but not limited to, prolate hemispheroid (a shape obtained by dividing a spheroid obtained with the major axis of an ellipse as a rotation axis, into two pieces along the minor axis).

Emission surface 330 is formed to protrude from flange part 370 on the front side (light diffusion plate 120 side) of light flux controlling member 300, and disposed to intersect central axis CA of light flux controlling member 300. Emission surface 330 emits, to outside, the light having entered light flux controlling member 300 while controlling the travelling direction of the light. Emission surface 330 is rotationally symmetrical (circularly symmetrical) about central axis CA.

In the present embodiment, emission surface 330 includes first emission surface 330a disposed in a predetermined range around central axis CA (the vicinity of central axis CA), and second emission surface 330b disposed to surround first emission surface 330a on the front side of light flux controlling member 300. In the present embodiment, first emission surface 330a is a smooth curved surface recessed with respect to light diffusion plate 120, and second emission surface 330b is a smooth curved surface protruded with respect to light diffusion plate 120 and connected to the top surface of flange part 370.

Rear surface 340 is a surface disposed on the rear side of light flux controlling member 300, and is a surface on the side opposite to emission surface 330.

Reflection part 350 is disposed to surround incidence surface 320 (recess 310) on the rear side of light flux controlling member 300, and includes inclined surfaces for reflecting light emitted from light-emitting element 220 and Fresnel-reflected by emission surface 330 (in the present embodiment, first inclined surface 361, second inclined surface 362, and a plurality of ridges 360 with ridgeline 363) (see FIG. 5E).

Preferably, the position of reflection part 350 is, but not limited to, a region where a large quantity of light emitted from the light emission center of light-emitting element 220, entered from incidence surface 320, and Fresnel-reflected by emission surface 330 (first emission surface 330a and second emission surface 330b) reaches. Preferably, reflection part 350 is disposed on the outside (a position separated from central axis CA) of the highest portion in light flux controlling member 300.

Preferably, the above-described reflection part 350 includes the plurality of ridges 360 (total reflection prism) from the viewpoint of improving the reflectivity of the light arriving from emission surface 330.

In bottom view, the plurality of ridges 360 is disposed in a radial manner (a rotationally symmetrical manner) with respect to central axis CA of light flux controlling member 300. As illustrated in FIG. 5E, each ridge 360 includes first inclined surface 361 with a flat shape, second inclined surface 362 with a flat shape, and ridgeline 363 as an intersection line of first inclined surface 361 and second inclined surface 362, and functions as a total reflection prism. As illustrated in FIG. 5D, a virtual line including ridgeline 363 of ridge 360 intersects central axis CA at a position on the front side (light diffusion plate 120 side) than ridgeline 363. Specifically, each ridge 360 is tilted at a predetermined angle (e.g., 30°) with respect to central axis CA such that it is closer to central axis CA on the front side (light diffusion plate 120 side) than on the rear side (light-emitting element 220 side). The light having reached reflection part 350 is sequentially reflected, toward emission surface 330, by the two surfaces (first inclined surface 361 and second inclined surface 362) of given ridge 360.

Flange part 370 is disposed between the outer edge of emission surface 330 and the outer edge of rear surface 340 and extended in the direction away from central axis CA. The shape of flange part 370 is a substantially annular shape. Flange part 370 makes it is easy to handle and align light flux controlling member 300. The thickness of flange part 370 is not limited, and is determined in consideration of the required area of emission surface 330, the moldability of flange part 370 and the like.

Light flux controlling member 300 may include a plurality of leg parts 380 (see FIG. 5B). The plurality of leg parts 380 is substantially columnar members protruded from rear surface 340. The plurality of leg parts 380 supports light flux controlling member 300 at an appropriate position with respect to light-emitting element 220.

### Light-Emitting Element

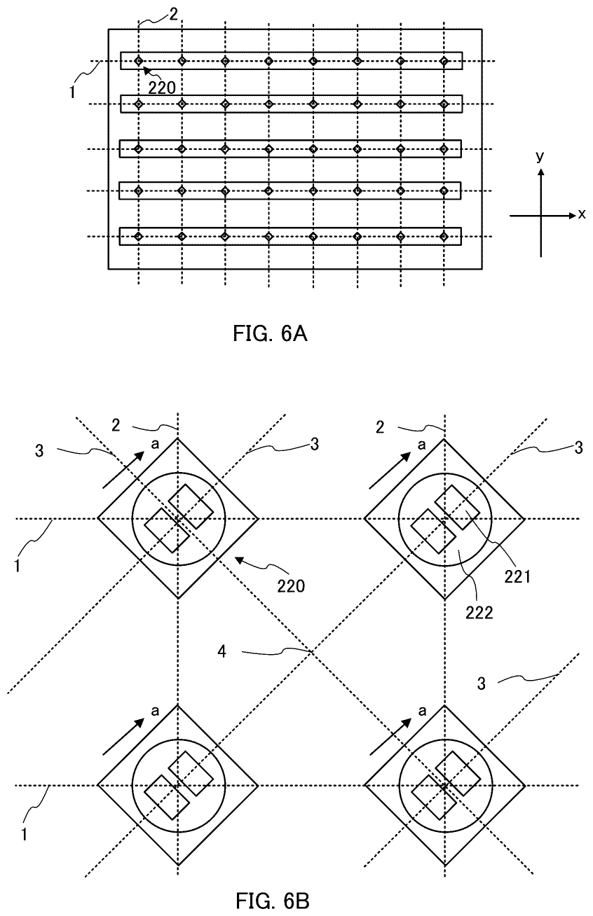

FIG. 6A illustrates a state where light flux controlling member 300 is removed from light-emitting device 200 in FIG. 4A, and illustrates a state where light-emitting element 220 is visible. In addition, FIG. 6B is a partially enlarged view of FIG. 6A.

As with light-emitting device 200, light-emitting element 220 needs only to be disposed at each intersection of a grid composed of the plurality of X-direction lines 1 extending in the X direction and the plurality of Y-direction lines 2 extending in the Y direction perpendicular to the X direction. More specifically, preferably, light-emitting element 220 is disposed such that its optical axis LA (see FIG. 4B) coincides with the above-described intersection in plan view. Note that optical axis LA of the light-emitting element means a central light beam of a stereoscopic light flux emitted from light-emitting element 220. Alternatively, preferably, light-emitting element 220 is disposed such that the center (center of gravity) of light-emitting surface 225 coincides with the intersection. In the present embodiment, light-emitting surface 225 has a circular shape, and the center (center of gravity) of light-emitting surface 225 is a center of the light-emitting surface having a circular shape.

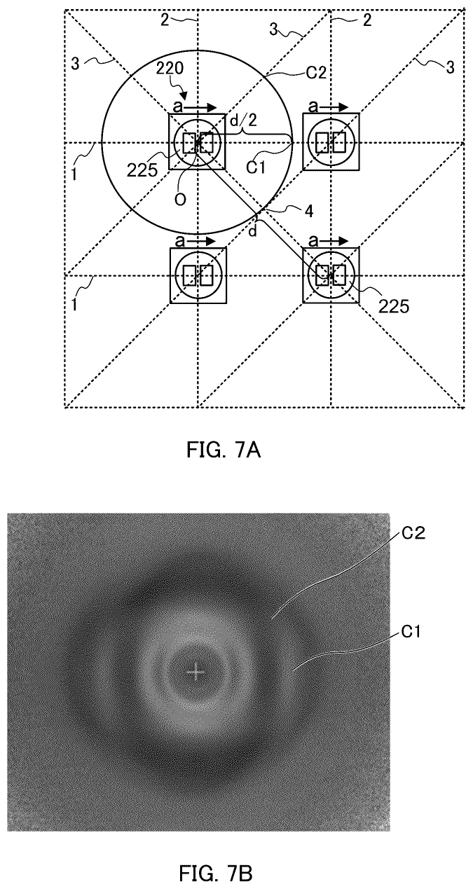

As illustrated in FIG. 7A, when it is assumed that d represents the distance between the center of light-emitting surface 225 of given light-emitting element 220 and the center of light-emitting surface 225 of adjacent light-emitting element 220 on diagonal line 3 of the grid, and light-emitting element 220 is disposed in the following manner, light-emitting element 220 has the following light distribution in combination with the light flux controlling member. Note that this light distribution is light distribution obtained on the assumption that only one light-emitting element 220 emits light.

Specifically, light-emitting element 220 satisfies Cy1>Cy2 when it is assumed that light-emitting element 220 is disposed such that direction a and the X direction (X-direction line 1) are parallel to each other as illustrated in FIG. 7A, Cy1 is a y-value of the chromaticity coordinates at first intersection C1, and Cy2 is a y-value of the chromaticity coordinates at second intersection C2, first intersection C1 being a point where a line passing through point O and being parallel to direction a and a virtual circle intersect each other, second intersection C2 being a point where a line passing through point O and being parallel to a diagonal line of the grid and the virtual circle intersect each other, the virtual circle being a circle with a radius of d/2 around point O located directly above the center of light-emitting surface 225 of light-emitting element 220 and set on the surface of light diffusion plate 120 on light-emitting device 200 side. This means that the yellow is stronger in the X direction than in the diagonal line direction, and the blue is stronger in the diagonal line direction than in the X direction. Note that the “chromaticity coordinates” mean the coordinates in the CIE chromaticity diagram.

FIG. 7B illustrates an example of a simulation result of a chromaticity distribution when it is assumed that the above-described arrangement is used. FIG. 7B illustrates the above-described first intersection C1 and second intersection C2. In addition, in FIG. 7B, closer to black indicates stronger blue, and closer to white indicates stronger yellow.

As is clear from FIG. 7B, C1 is whiter and has stronger yellow than C2. More specifically, in the present embodiment, Cy1, which is the y-value of the chromaticity coordinates at C1, is 0.264, and Cy2, which is the y-value of the chromaticity coordinates at C2, is 0.255, and thus Cy1>Cy2 is satisfied. In addition, ΔCy is 0.009, where Cy1-Cy2 is ΔCy.

The above-described light-emitting element 220 provides the effects of the present invention when disposed in the following manner. Specifically, each light-emitting element 220 is disposed such that a point where the Cy is greater than the Cy2 is located on a line parallel to diagonal line 3 of the grid on the virtual circle. In this manner, generation of uneven color with strong blue in the region around intersection 4 of the two diagonal lines 3 of the grid illustrated in FIG. 6B can be suppressed. Note that in the present embodiment, direction a is a direction in which two blue LED chips 221 with a rectangular shape with long sides and short sides are disposed in parallel. In addition, in the present embodiment, two blue LED chips 221 have the same shape. In addition, in the present embodiment, direction a is a direction perpendicular to the long side of the rectangular shape.

Note that preferably, ΔCy>0.003, more preferably ΔCy>0.005, still more preferably ΔCy>0.009, holds, where Cy1-Cy2 is ΔCy.

In addition, preferably, each of the plurality of light-emitting elements 220 is disposed such that the point where Cy is greater than (Cy1+Cy2)/2 is located on a line parallel to diagonal line 3 of the grid on the virtual circle. In addition, more preferably, each of the plurality of light-emitting elements 220 is disposed such that the point where Cy is Cy1 is located on a line parallel to diagonal line 3 of the grid on the virtual circle. In addition, preferably, the difference between the maximum value of Cy and the minimum value of Cy in the surface light source device is 0.008 or smaller, more preferably 0.005 or smaller.

As illustrated in FIG. 6B, while each grid includes two diagonal lines 3, it is preferable that light-emitting element 220 be disposed in the above-mentioned manner regarding one diagonal line 3 from a view point of suppressing uneven color in the region around intersection 4. In addition, it is preferable that light-emitting element 220 be disposed in the above-mentioned manner regarding each of the plurality of diagonal lines 3 parallel to each other from a view point of generally suppressing the uneven color of surface light source device 100. In addition, it is preferable that directions a of the plurality of light-emitting elements 220 are all parallel to one another in the surface light source device.

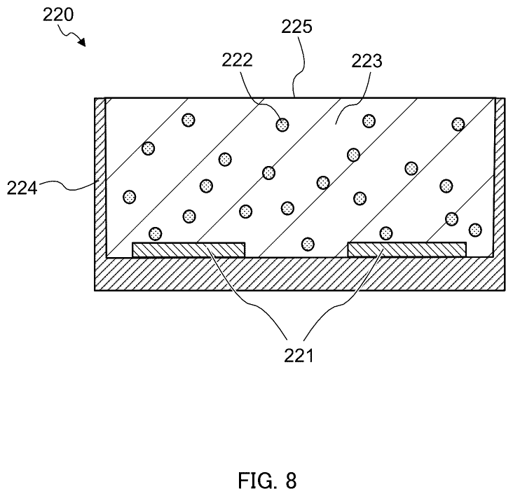

FIG. 8 is a sectional view of light-emitting element 220. In the present embodiment, light-emitting element 220 is a white LED package. Such a light-emitting element 220 includes two blue LED chips 221, yellow phosphor 222 disposed to cover blue LED chip 221 and its periphery, and sealing member 223 that seals two blue LED chips 221 and yellow phosphor 222. In the present embodiment, a plurality of blue LED chips 221 is disposed inside resin frame 224, and sealing member 223 is provided in resin frame 224.

In light-emitting element 220, blue light is emitted from the plurality of blue LED chips 221. When a part of the emitted blue light impinges on yellow phosphor 222 in sealing member 223, yellow light is generated from yellow phosphor 222, and the yellow light is emitted from light-emitting surface 225. On the other hand, another part of the blue light is emitted as it is from light-emitting surface 225 without impinging on yellow phosphor 222 in sealing member 223. White light is obtained when yellow light and blue light emitted from light-emitting surface 225 are mixed. In this case, it is preferable that the intensity of blue light and the intensity of yellow light emitted from light-emitting surface 225 of light-emitting element 220 be substantially the same. Note that in the present embodiment, light-emitting surface 225 has a circular shape in plan view as illustrated in FIG. 7A.

Blue LED chip 221 is a semiconductor element that emits light with wavelengths in the blue region. For example, blue LED chip 221 emits blue light with a light-emission wavelength band of about 450 nm to 460 nm. The shape of the light-emitting surface of blue LED chip 221 is, but not limited to, a rectangular shape, for example. The plurality of blue LED chips 221 is disposed in resin frame 224.

The combination of the LED chip and the phosphor is not limited to the above-mentioned combination of the blue LED chip and the yellow phosphor. The LED chip needs only to emit light of a first color and the phosphor needs only to convert the incident light of the first color into light of a second color. Preferably, the light of the first color and the light of the second color have a relationship of complementary color, for example. In addition, preferably, the light of the first color and the light of the second color become white light when mixed.

### Simulations

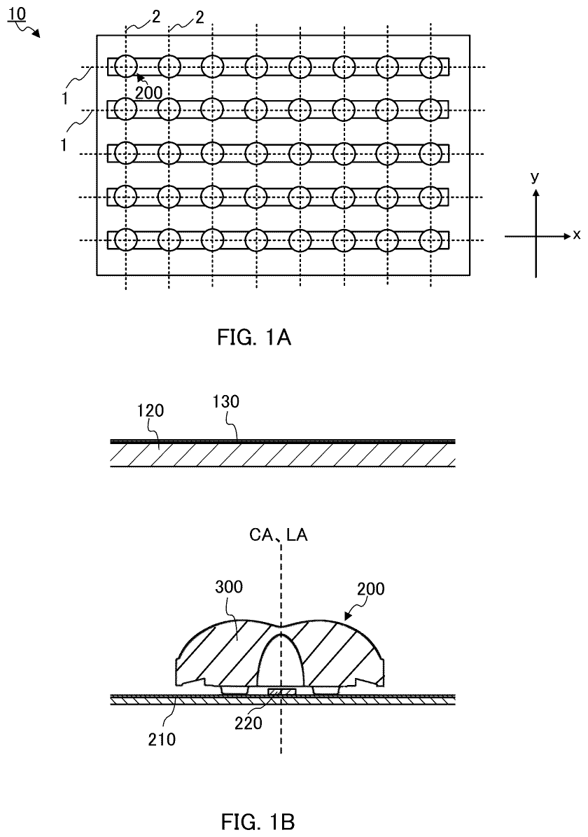

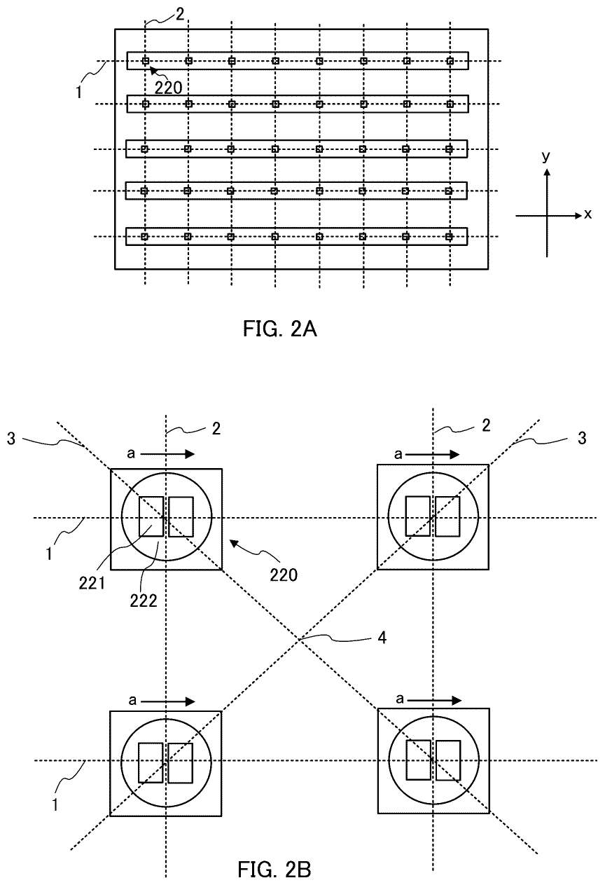

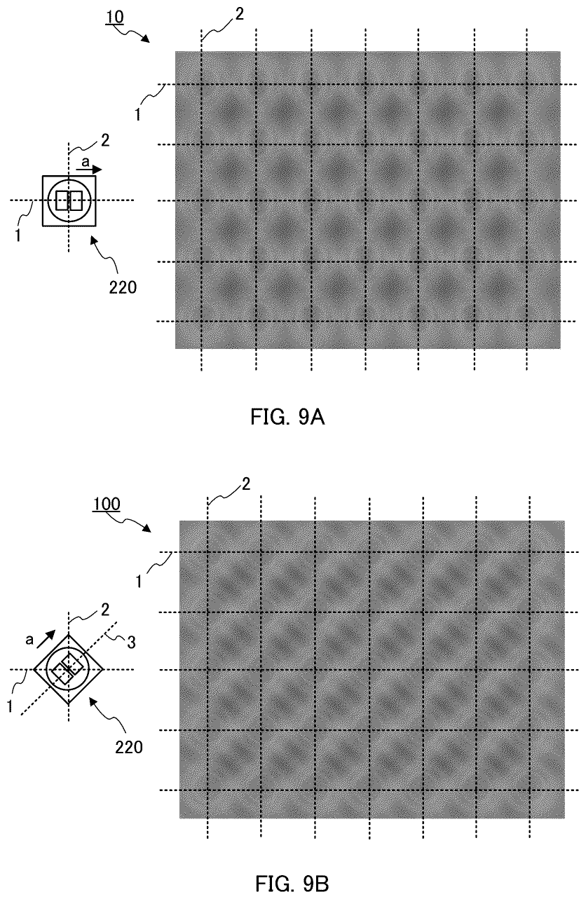

FIG. 9A illustrates a chromaticity distribution on the light diffusion plate in surface light source device 10 of a comparative example illustrated in FIGS. 1A, 2A and 2B, and FIG. 9B illustrates a chromaticity distribution on the light diffusion plate in surface light source device 100 according to the present embodiment.

In FIGS. 9A and 9B, light-emitting device 200 is disposed at the intersection of the plurality of X-direction lines 1 and the plurality of Y-direction lines 2. In addition, as illustrated in FIG. 9A, in surface light source device 10 of the comparative example, light-emitting element 220 is disposed such that direction a is parallel to X-direction line 1. On the other hand, as illustrated in FIG. 9B, in the present embodiment, light-emitting element 220 is disposed such that direction a is not parallel to the X direction and the Y direction. More specifically, in the present embodiment, light-emitting element 220 is disposed such that the point where Cy is Cy1 is located on a line parallel to diagonal line 3 of the grid (disposed such that direction a and diagonal line 3 are parallel to each other).

In FIGS. 9A and 9B, closer to black indicates stronger blue, and closer to white indicates stronger yellow. As is clear from the comparison between FIGS. 9A and 9B, uneven color is generated with a portion with strong blue in the region around the intersection of two diagonal lines of the grid in FIG. 9A. Conversely, in FIG. 9B, the uneven color in the region around the intersection of the diagonal lines of the grid is suppressed. A possible reason for this is that the generation of the region with strong blue in the region around the intersection of the diagonal lines of the grid due to the interference of the light is suppressed because light-emitting elements 220 is disposed in the above-described manner in the present embodiment.

### Effect

With the surface light source device according to the present embodiment, the generation of uneven color in the surface light source device can be suppressed.

### INDUSTRIAL APPLICABILITY

The surface light source device of the present invention is applicable to a backlight of a liquid crystal display device, a generally-used illumination device, and the like, for example.

### REFERENCE SIGNS LIST

1 X-direction line
2 Y-direction line
3 Diagonal line
4 Intersection of diagonal lines
10, 100 Surface light source device
100′ Display device
102 Display member
110 Housing
112 Bottom plate
114 Top plate
120 Light diffusion plate
130 Optical sheet
200 Light-emitting device
210 Substrate
220 Light-emitting element
221 Blue LED chip
222 Yellow phosphor
223 Sealing member
224 Resin frame
225 Light-emitting surface
300 Light flux controlling member
310 Recess
320 Incidence surface
330 Emission surface
330a First emission surface
330b Second emission surface
340 Rear surface
350 Reflection part
360 Ridge
361 First inclined surface
362 Second inclined surface
363 Ridgeline
370 Flange part
380 Leg part
CA Central axis
LA Optical axis

1. A surface light source device comprising:
a plurality of light-emitting devices disposed on a substrate;
a light diffusion plate separated from the plurality of light-emitting devices and disposed on a side opposite to the substrate with respect to the plurality of light-emitting devices; and
an optical sheet disposed on a side opposite to the plurality of light-emitting devices with respect to the light diffusion plate,
wherein the plurality of light-emitting devices is disposed at respective intersections of a grid comprising a plurality of X-direction lines extending in a X direction and a plurality of Y-direction lines extending in a Y direction perpendicular to the X direction,
wherein each of the plurality of light-emitting devices includes a light-emitting element and a light flux controlling member,
wherein the light-emitting element includes two LED chips aligned in a direction a and configured to emit light of a first color, and a phosphor disposed to cover the LED chip and a periphery of the LED chip and configured to convert the light of the first color into light of a second color,
wherein Cy1>Cy2 is satisfied when d represents a distance between a center of a light-emitting surface of a given light-emitting element and a center of a light-emitting surface of an adjacent light-emitting element on a diagonal line of the grid, it is assumed that in each of the plurality of light-emitting devices, the light-emitting element is disposed such that the direction a and the X direction are parallel to each other, Cy1 is a y-value of chromaticity coordinates at a first intersection C1, and Cy2 is a y-value of chromaticity coordinates at a second intersection C2, the first intersection C1 being a point where a line passing through a point O and being parallel to the direction a and a virtual circle intersect each other, the second intersection C2 being a point where a line passing through the point O and being parallel to the diagonal line of the grid and the virtual circle intersect each other, the virtual circle being a circle with a radius of d/2 around the point O located directly above a center of a light-emitting surface of the light-emitting element and set on a surface of the light diffusion plate on the light-emitting device side, and
wherein each of the plurality of light-emitting elements is disposed such that a point where Cy is greater than Cy2 is located on a line parallel to the diagonal line of the grid on the virtual circle.

2. The surface light source device according to claim 1, wherein ΔCy≥0.003 holds, where Cy1-Cy2 is ΔCy.

3. The surface light source device according to claim 1, wherein each of the plurality of light-emitting elements is disposed such that a point where Cy is greater than (Cy1+Cy2)/2 is located on a line parallel to the diagonal line of the grid on the virtual circle.

4. The surface light source device according to claim 1, wherein each of the plurality of light-emitting elements is disposed such that a point where Cy is Cy1 is located on a line parallel to the diagonal line of the grid on the virtual circle.

5. The surface light source device according to claim 1, wherein a difference between a maximum value of Cy and a minimum value of Cy in the surface light source device is 0.008 or smaller.

6. The surface light source device according to claim 1, wherein the optical sheet is a prism sheet, a diffusion sheet, a DBEF, or a combination of two or more of them.

7. The surface light source device according to claim 1, wherein the LED chip has a rectangular shape in plan view.

8. The surface light source device according to claim 1, wherein the light-emitting surface of the light-emitting element has a circular shape in plan view.

9. The surface light source device according to claim 1, wherein an incidence surface and an emission surface of the light flux controlling member are circularly symmetrical.

10. A display device comprising:
the surface light source device according to claim 1; and
a display member configured to be irradiated with light emitted from the surface light source device.
